(19) United States
(12) Patent Application Publication
(10) Pub. No.: US 2004/0012071 A1
(43) Pub. Date: Jan. 22, 2004

(54) Semiconductor device, and method for manufacturing semiconductor device

(75) Inventors: Yasuhiro Ido, Tokyo (JP); Takeshi Iwamoto, Tokyo (JP)

Correspondence Address: McDermott, Will & Emery, 600 13th Street, N.W., Washington, DC, 20005-3096, US

(73) Assignee: MITSUBISHI DENKI KABUSHIKI KAISHA

(21) Appl. No.: 10/350,093

(22) Filed: Jan. 24, 2003

(30) Foreign Application Priority Data
Jul. 22, 2002 (JP) 2002-212120

(51) Int. Cl. H01L 29/00; H01L 21/82; H01L 21/44

(52) U.S. Cl. 257/529; 438/601; 438/132

(57) ABSTRACT

A semiconductor device includes a substrate, a fuse that can be blown by the radiation of light formed above the substrate, and insulating films formed on the fuse and on the substrate. One of the insulating films includes a flat portion formed on the substrate and the surface thereof is higher than the surface of the fuse, and a protruded portion formed on the fuse continuously from the flat portion, and protruded from the surface of the flat portion.

### BACKGROUND OF THE INVENTION

1. Field of the Invention

The present invention relates to a semiconductor device, and a method for manufacturing a semiconductor device. More specifically, the present invention relates to a semiconductor device comprising a portion used as a fuse, and a method for manufacturing such a semiconductor device.

2. Background Art

In order to secure the yield in semiconductor manufacturing processes accompanying the recent size reduction, capacity increase, and speed elevation of semiconductor devices, a redemption method has been adopted, wherein a spare memory cell is previously contained in a semiconductor device, and if a defective bit is found, the defective bit is substituted by the spare memory cell. As a method for substituting the defective bit with the spare memory cell, a method has been used, wherein a portion used as a fuse has previously been provided in a wiring layer, and the fuse is blown, thereby a programming to transmit the signal to use the spare memory cell is executed. Also as a method for blowing the fuse, the laser trimming method has widely been used.

Referring to FIGS. 7 and 8, the structures of a fuse used in such a case will be described below.

FIG. 7 is a sectional view for illustrating the portion where a fuse 2 is formed in a conventional semiconductor device 200. FIG. 8 is a concept diagram showing the state where the fuse 2 is blown: FIG. 8A shows the top surface of the fuse 2, and FIG. 8B is a sectional view showing the state where the fuse 2 in the same portion as the cross section of the semiconductor device 200 shown in FIG. 7 is blown.

As FIG. 7 shows, in the semiconductor device 200, the fuse 2 is formed on an intervening oxide film 8 on a substrate 6. On the fuse 2 is formed an oxide film 10 so as to bury the fuse 2. The upper portion of the oxide film 10 is planarized using the CMP (chemical mechanical polishing) method or the like. A wiring layer laminated with forming a wiring is used as the fuse 2 as it is. The wiring layer is formed by laminating a barrier metal layer 12, a metal layer 14, and an antireflective film layer 16.

To blow the fuse 2 thus formed, laser beams are radiated from the laser 26 above the oxide film 10 as FIG. 8 shows. The radiated laser beams are transmitted through the oxide film 10, and reach the fuse 2. The fuse 2 is blown, and a hole 40 is formed in the oxide film 10. Specifically, by absorbing the laser beams, the fuse 2 is liquefied, and vaporized, thereby cracks occur resulting in explosion. This explosion blows the fuse 2, and forms a hole 40 in the oxide film 10.

The absorption of laser beams by the fuse 2 mainly takes place at both end portions 30 of the fuse 2 contacting the oxide film 10 of the lowermost barrier metal layer 12, and on the surface portion 32 of the uppermost antireflective film layer 16. In particular, the laser beams are markedly absorbed on the surface portion 32 of the uppermost antireflective film layer 16. Therefore, the cracking and explosion of the fuse 2 are considered to occur mainly on the surface portion 32 of the uppermost antireflective film layer 16.

However, when much laser beams are absorbed in the both end portions 30 of the barrier metal layer 12, cracking and explosion occur not only on the surface portion 32 of the antireflective film layer 16, but also in the both end portions 30. In such a case, the oxide film 10 is destroyed also from the lowermost layer portion of the fuse 2, and as a result, a hole 40 larger than the predetermined size may be formed in the oxide film 10.

When the oxide film 10 on the fuse 2 is thick, even if light absorption in the barrier metal layer 12 is small, an additional pressure for exploding the fuse 2 will be required. Since the lower surface of the barrier metal layer 12 of the fuse 2 is the boundary of films, the mechanical strength is low. Therefore, the cracks from the bottom of the fuse 2 develop easily, explosion occurs in this portion, and as a result, a hole 40 larger than the predetermined size may also be formed.

In general, a fuse region (not shown) is provided in a semiconductor device, and a plurality of such fuses as described above are provided adjacent to each other in the fuse region. Therefore, if the hole 40 is larger than the predetermined size as described above, there may be the case where not only a target fuse 2, but also adjacent fuses are damaged.

### SUMMARY OF THE INVENTION

Therefore, in order to solve the above described problems, to prevent damage to adjacent fuses, and to blow only the target fuse more securely, the present invention is to propose an improved semiconductor device, and a method for manufacturing such a semiconductor device.

According to one aspect of the present invention, a semiconductor device comprises a substrate, a fuse formed above the substrate, and blown by the radiation of light, and an insulating film formed on the fuse and on the substrate. The insulating films comprises a flat portion disposed on the substrate, whose surface is above the surface of the fuse, and a protruded portion formed on the fuse continuously from the flat portion, and protruded from the surface of the flat portion.

Accordingly, the laser beams can be concentrated on the surface of the fuse, and therefore, the fuse to be blown can be blown more securely.

Other and further objects, features and advantages of the invention will appear more fully from the following description.

### BRIEF DESCRIPTION OF THE DRAWINGS

FIG. 1 is a front schematic plan for illustrating a fuse 2 used in an embodiment of the present invention;

FIGS. 2 and 3 are a schematic sectional views for illustrating a portion whereon the fuse is formed in a semiconductor device 100 in the embodiment of the present invention;

FIG. 4 is a schematic sectional view for illustrating the state where the fuse 2 is irradiated by laser beams in the embodiment of the present invention;

FIGS. 5A and 5B are schematic diagrams for illustrating the state where the fuse 2 has been blown in the embodiment of the present invention;

FIG. 6 is a flow diagram for describing the method for forming a fuse 2 in a semiconductor device 100 in the embodiment of the present invention;

FIG. 7 is a sectional view for illustrating the portion where a fuse 2 is formed in a conventional semiconductor device 200;

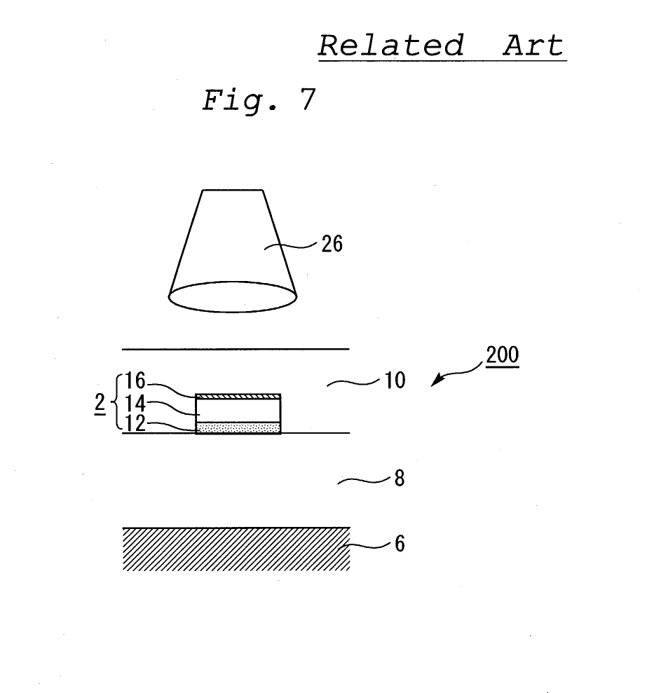

FIGS. 8A and 8B are concept diagrams showing the state where the fuse 2 is blown:

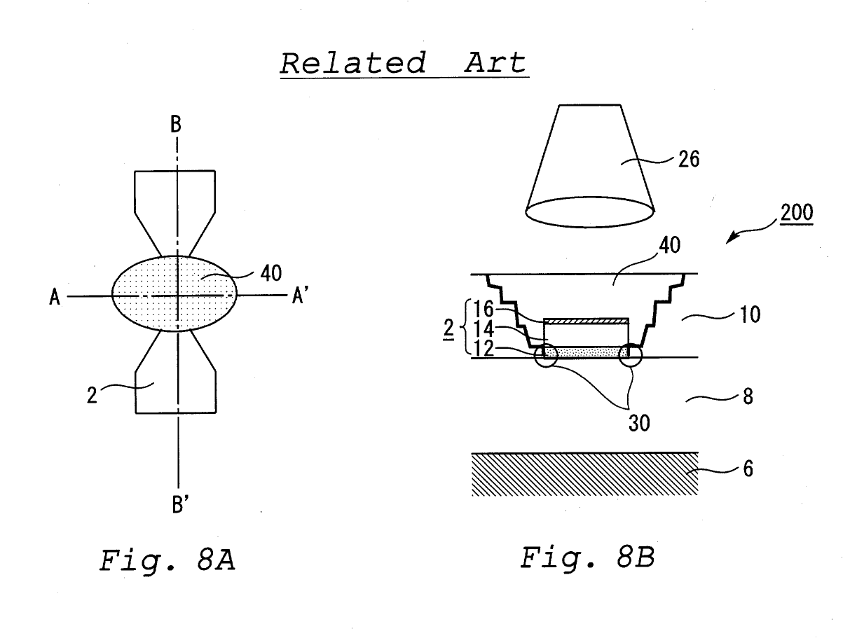

### DETAILED DESCRIPTION OF THE PREFERRED EMBODIMENTS

An embodiment of the present invention will be described below referring to the drawings. In the drawings, the same or corresponding parts will be denoted by the same reference numerals, and the description thereof will be simplified or omitted.

Embodiment

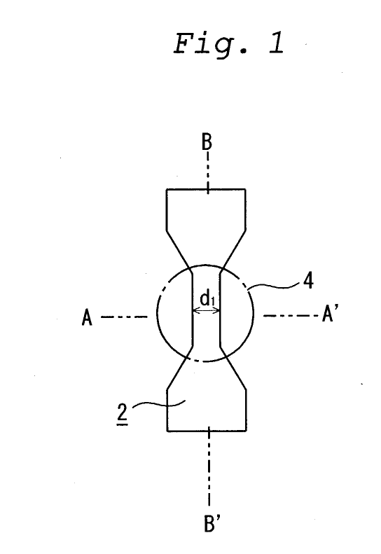

FIG. 1 is a front schematic plan for illustrating a fuse 2 used in an embodiment of the present invention.

As FIG. 1 shows, the fuse 2 is formed so that the center portion is narrower than the both end portions (in FIG. 1, the upper and lower portions). The width of the center portion, d₁, is 0.6 to 1.2 μm. To blow such a fuse 2, laser beams 4 are radiated to the center portion.

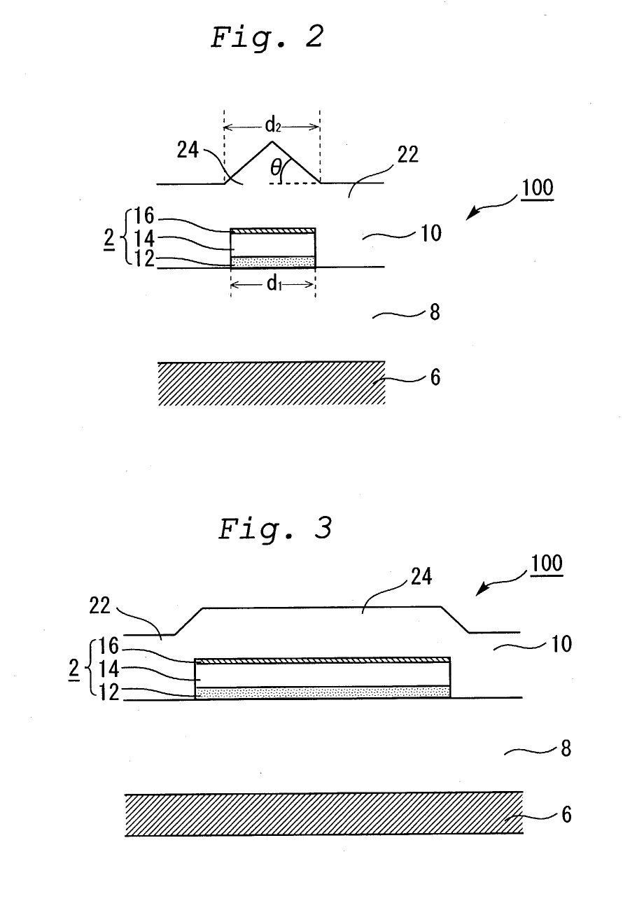

FIGS. 2 and 3 are a schematic sectional views for illustrating a portion whereon the fuse is formed in a semiconductor device 100 in the embodiment of the present invention; FIG. 2 shows the cross section along the A-A′ direction in FIG. 1; and FIG. 3 shows the cross section along the B-B′ direction in FIG. 1.

As FIGS. 2 and 3 show, the semiconductor device 100 comprises a fuse 2, an Si substrate 6, and oxide films 8 and 10.

An oxide film 8 is formed on the Si substrate 6. A fuse 2 is formed on the oxide film 8. Another oxide film 10 is formed on the fuse 2 and the oxide film 8 so as to cover the portion exposed on the fuse 2 and the oxide film 8. In other words, the fuse 2 is buried in the oxide film 10.

The fuse 2 is composed of a barrier metal layer 12, a metal layer 14, and an antireflective film layer 16. The barrier metal layer 12 is formed on the oxide film 8. The metal layer 14 is formed on the barrier metal layer 12, and the antireflective film layer 16 is formed on the metal layer 14.

The oxide film 10 has a flat portion 22 and a protruded portion 24.

The flat portion 22 is a portion of the oxide film 10 whose surface is flat. The flat portion 22 is formed mainly on the portion whereon the fuse 2 is not formed, so as to be in contact with the oxide film 8. The surface of the flat portion 22 is formed so as to be higher than the surface of the antireflective film layer 16 of the fuse 2.

The protruded portion 24 is the other portion of the oxide film 10 formed continuously from the flat portion 22, and protruded from the surface of the flat portion 22. The protruded portion 24 is formed mainly on the fuse 2. The protruded portion 24 has a triangular ridge shape in the lateral cross section in the center portion of the fuse 2 as shown in FIG. 2. The width of the base of the protruded portion 24 in the lateral cross section, d₂, is the same as the width of the center portion of the fuse 2, d₁, and is 0.6 to 1.2 μm here. The angle of inclination of the protruded portion 24 to the surface of the flat portion 22, θ, is about 40 to 70 degrees.

A plurality of fuses as described above are formed in a fuse region (not shown) provided on the semiconductor device 100. Also, a memory region (not shown) and the like are provided around the fuse region (not shown). When there is a defective bit or the like in a memory cell, the fuse 2 is blown by radiating laser beams, and thereby a program to replace the memory cell having the defective bit with a spare memory cell can be executed.

In the memory cell region (not shown) on the semiconductor device 100, a wiring layer of the same constitution as the fuse 2 is formed on the same layer as the layer whereon the fuse 2 was formed, and this wiring layer is used as an aluminum pad.

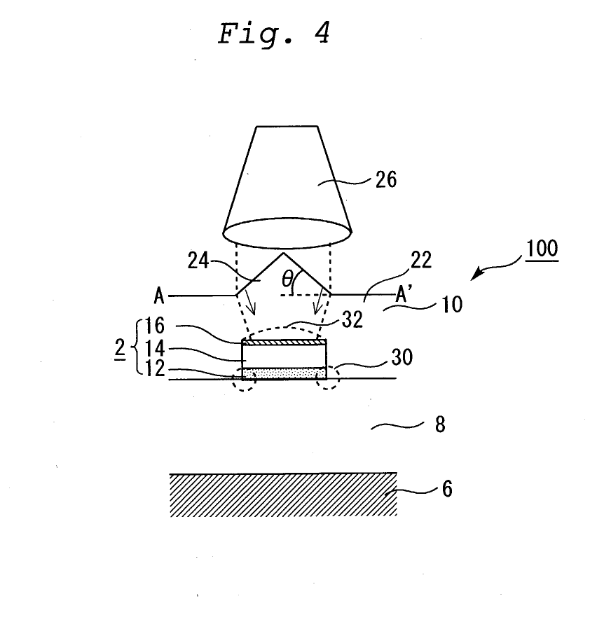

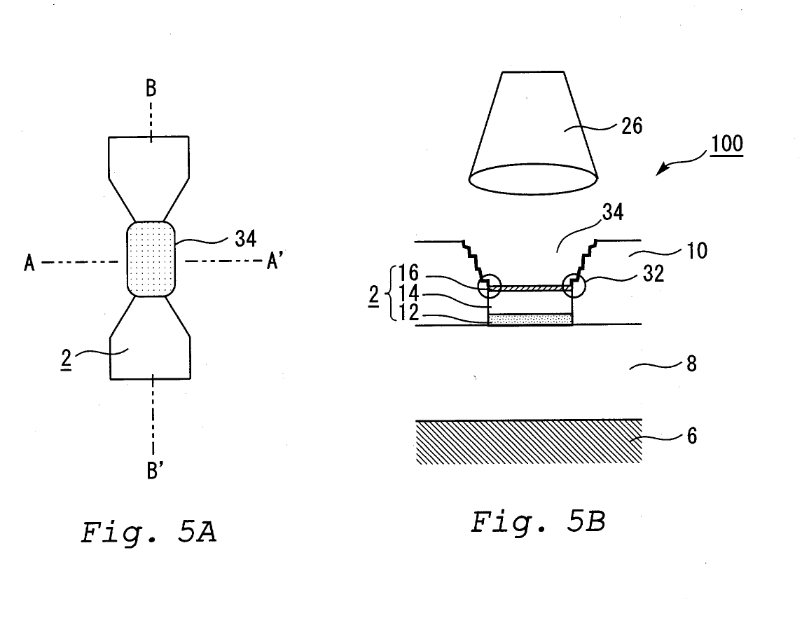

FIG. 4 is a schematic sectional view for illustrating the state where the fuse 2 is irradiated by laser beams, and shows the cross section along the A-A′ direction in FIG. 1. FIG. 5 is a schematic diagram for illustrating the state where the fuse 2 has been blown; FIG. 5A shows the upper surface of the fuse 2; and FIG. 5B shows the state where the fuse 2 of the same portion as the cross section of the semiconductor device 100 shown in FIG. 2 has been blown.

As shown by the arrow in FIG. 4, the laser 26 is placed in the position so that the radiated laser beams irradiate mainly the protruded portion 24 of the oxide film 10. The oxide film 10 can refract and transmit the laser beams at the protruded portion 24 thereof. The protruded portion 24 is formed to have the angle of inclination θ, so that the transmitted laser beams irradiate mainly the antireflective film layer 16 of the fuse 2. Since the flat portion 22 of the oxide film 10 is formed so that the surface thereof is higher than the surface of the antireflective film layer 16 of the fuse 2, and the protruded portion 24 of the fuse 2 is continuously formed from the flat portion 22, the laser beams refracted at the oxide film 10 do not irradiate the side portions of the fuse 2. In other words, by refracting the laser beams by the protruded portion 24 of the oxide film 10, the laser beams are concentrated in the center so as to irradiate the uppermost layer of the fuse 2, i.e., the antireflective film layer 16.

Of the three layers of the fuse 2, although layers that absorb the laser beams are the barrier metal layer 12 and the antireflective film layer 16, here, the radiation of the laser beams are concentrated on the antireflective film layer 16. Therefore, the portion to absorb the laser beams is mainly the surface portion 32 of the antireflective film layer 16.

Thereby, the liquefaction and vaporization of the fuse 2, and cracking and explosion due to these occur mainly at the surface portion 32 of the antireflective film layer 16 where the laser beams are absorbed. As a result, as FIGS. 5A and 5B show, when the fuse 2 is blown, the hole 34 formed in the oxide film 10 can be of a shape that opens only on the surface portion 32 of the antireflective film layer 16.

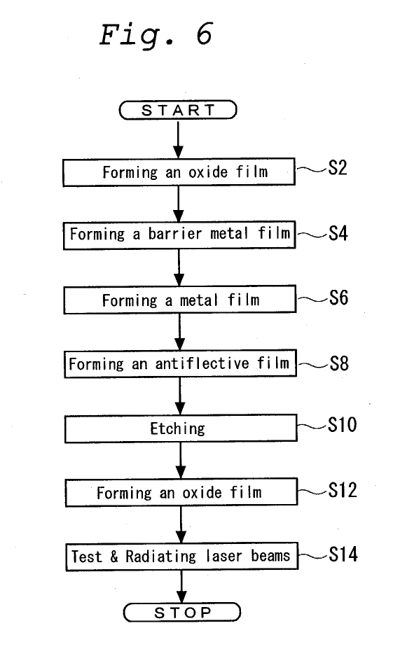

FIG. 6 is a flow diagram for describing the method for forming a fuse 2 in a semiconductor device 100, and for blowing the fuse 2, according to this embodiment.

A method for manufacturing a semiconductor device 100 according to this embodiment will be described referring mainly to FIG. 6.

First, an oxide film 8 is formed on an Si substrate 6. Here, the oxide film 8 is formed using the CVD (chemical vapor deposition) method, and then planarized using the CMP (chemical mechanical polishing) method (Step S2).

Next, a laminated film consisting of a barrier metal layer 12, a metal layer 14, and an antireflective film layer 16 is formed on the oxide film 10 (Steps S4 to S8). Here, each layer is laminated using the PVD (physical vapor deposition) method. The laminated film consisting of a barrier metal layer 12, a metal layer 14, and an antireflective film layer 16 is used as an aluminum pad (not shown) in a memory cell region (not shown). In other words, the fuse 2 is formed in a fuse region (not shown) simultaneously with the step of forming the aluminum pad (not shown) in a memory cell region (not shown).

Next, the laminated film is etched (Step S10). Thereby, a required aluminum pad (not shown) is formed in the memory region (not shown), and a plurality of fuses 2 are formed in the fuse region (not shown).

Next, an oxide film 10 is formed on the fuse 2 or the aluminum pad (not shown), or the oxide film 8 (Step S12). Here, the oxide film 10 is formed using the HDP (high-density plasma CVD) method. Here, as FIG. 2 shows, the oxide film 10 is protruded on the fuse 2 upward with respect to the oxide film 8 by the height of the fuse 2. Therefore, if the HDP method is used, the oxide film 10 is formed so as to triangularly protrude on the fuse 2.

Specifically, using the HDP method, deposition of the oxide film 10 takes place simultaneously with the etching of the deposited oxide film. Here, etching takes place easier in the angled portion. Therefore, the oxide film is deposited along the surface of the fuse 2 and the oxide film 8, and at the same time, the angled portion, that is, oxide films formed in the vicinity of four corners of the fuse 2 in FIG. 2 are etched. Deposition and etching further proceed, and when the portion having a sharper angle is formed, etching proceeds in this portion. By thus repeating deposition and etching, unevenness is removed, and a triangular protruded portion is formed on the fuse 2.

Here, the sputtering yield is adjusted so as to be a maximum when the incident angle of plasma ions is 45 degrees, and the conditions of HDP are determined so that the angle of inclination of the protruded portion 24 becomes 40 to 70 degrees.

Thus, the semiconductor device 100 is formed.

Next, when a defective bit is found in the memory cell in the thus formed semiconductor device 100 during the test or the like, and the need for replacement with a spare memory cell happens, laser beams are radiated onto the protruded portion 24 (Step S14). Here, the laser beams are first radiated from the laser 26. The laser beams impinge on the protruded portion 24, are refracted to the direction substantially perpendicular to the inclined surface, and are transmitted through the oxide film 10. Therefore, the laser beams that have been transmitted through the protruded portion 24 concentratively irradiate the surface portion 32 of the antireflective film layer 16 of the fuse 2. Here, since the laser beams are concentrated in the center direction due to refraction, they do not reach the both end portions 30 of the barrier metal layer 12. Also, the metal layer 14 underlying the antireflective film layer 16 does not transmit laser beams. Therefore, the laser beams do not reach the vicinity of the center of the barrier metal layer 12.

As described above, the fuse 2 is liquefied, vaporized, cracked, and eventually exploded from the surface portion 32 of the antireflective film layer 16 irradiated by laser beams. Thereby, the fuse 2 is blown, and a hole 34 is formed in the oxide film 10. Thus, when a defective bit is found, a semiconductor device 100 wherein the defective memory cell is replaced by a spare memory cell is formed.

As FIG. 5 shows, the laser beams can be refracted at the protruded portion 24, and concentrated onto the antireflective film layer 16, and thereby, the absorption of the laser beams by the both end portions 30 of the barrier metal layer 12 can be prevented. Therefore, cracking and explosion of the both end portions 30 of the barrier metal layer 12 can be prevented, and cracking and explosion can be made to occur only in the vicinity of the surface portion 32 of the antireflective film layer 16. Thereby, a small hole 34 can be formed in such a shape as to expose only the surface of the antireflective film layer 16. Namely, according to this embodiment, the fuse 2 can be blown by the small hole in the antireflective film layer 16 or so. This is also advantageous for the downsizing of semiconductor devices.

According to this embodiment, the protruded portion 24 formed on the fuse 2 when the oxide film 10 is formed can be utilized as it is. Therefore, planarization by CMP is not required. For this reason, the oxide film 10 having less variation of film thickness than in the case using the CMP method can be utilized as it is. Therefore, it is also advantageous in the control of film thickness on the fuse 2.

According to this embodiment, an oxide film 10 is formed as the uppermost layer of a semiconductor device 100, and a fuse 2 is formed immediately under the oxide film 10. Therefore, since the fuse 2 can be blown easily preventing the pressure produced when the fuse 2 is blown, the size of the hole 34 can be reduced. Therefore, this embodiment is advantageous also for downsizing semiconductor devices.

In this embodiment, oxide films 8 and 10 are used as insulating films. However, the insulating films in the present invention is not limited to oxide films, but other insulating films, such as nitride films, can also be used as long as they are transparent to light.

In this embodiment, only an oxide film 8 is formed between the Si substrate 6 and the layer whereon the fuse is formed. However, the present invention is not limited to this, but more than one layer, such as an insulating layer and a wiring layer, can be formed between the Si substrate 6 and the fuse 2.

In this embodiment, if more than one (n) metal wiring layer are formed, the last (n^{th}) wiring layer can be used as the fuse. Thereby, the triangular shape formed inevitably above the fuse 2 by the HDP method can be utilized, and the pressure produced by blown the fuse can be reduced. However, in the present invention, the fuse 2 is not limited to the last (n^{th}) wiring layer. In such a case, a protruded portion can be formed in each film formed on the fuse 2.

In this embodiment, the fuse 2 is constituted by laminating a barrier metal layer 12, a metal layer 14, and an antireflective film layer 16. This is for utilizing each layer deposited for forming the aluminum pad in the memory region as it is in the fuse region as the fuse. However, the present invention does not intend to be limited thereto, but the fuse may be formed by laminating other films, or may be formed of one film. Also, a step of forming the fuse 2 may be provided separately; or if the fuse is formed in the other layer, the same materials as the materials used for the wiring layer formed in the layer may be used as it is when the wiring layer is formed.

In this embodiment, the width of the center portion of the fuse 2, d₁, is 0.6 to 1.2 μm. This was decided considering pressure produced by blowing the fuse 2; however, the present invention does not intend to limit the width of the fuse within this range, but may be beyond this range as long as the pressure and the like are taken into consideration.

This embodiment is described for the case where the width of the base of the protruded portion 24, d₂, is the same as the width of the center portion of the fuse 2, d₁. This is for securely concentrating the laser beams onto the center portion without irradiating the both end portions 30 of the barrier metal layer 12, and for utilizing the oxide film 10 formed by the HDP method as it is. However, the present invention does not intend to be limited thereto, but the width of the base of the protruded portion 24, d₂, may be preferably equal to or larger than the width of the center portion of the fuse 2, d₁. The width d₂ may be a little smaller than the width d₁, if it can inhibit the absorption of the laser beams by the both end portions 30 of the barrier metal layer 12 to some extent.

In this embodiment, the protruded portion is described to have a triangular shape having an angle of 40 to 70 degrees. This is because the HDP method can easily produce a triangular shape, and the angle of 40 to 70 degrees can be controlled easily. The protrusion of the triangular shape having an angle of 40 degrees or more is preferable for concentrating laser beams. However, the present invention does not intend to limit the shape and angle thereto, but the protruded portion may have other shapes and other angles, as long as the protruded portion plays a role of a lens to refract light.

In this embodiment, each layer is formed using the CVD method or the PVD method. However, the present invention does not intend to be limited thereto, but other methods can be used if the properties and the like of each film are taken into consideration. In this embodiment, the oxide film 10 is formed using the HDP method. This is because a triangular protruded portion 24 can also be formed on the fuse 2 during the formation of the oxide film 10 by using the HDP method. However, the present invention does not intend to limit the method thereto, but any methods can be used, as long as the oxide film can be formed on the fuse 2 so as to play a role of a lens to refract light.

In the present invention, a substrate means a substrate disposed under a fuse, including a substrate wherein an insulating film, a wiring layer, and the like are formed. For example, that contains the Si substrate 6 and the oxide film 8 in the embodiment falls under this definition. In the present invention, the oxide film 10 in the embodiment falls under the insulating film. Also in the present invention, for example, the center portion of the fuse 2 in the embodiment falls under the portion of the fuse irradiated by light; and for example, the cross section of the portion shown in FIG. 2 falls under the cross section of the portion of the fuse irradiated by light.

In the embodiment, the step of forming the fuse of the present invention is performed by carrying out, for example, Steps S4 to Step S10; and the step of forming the insulating films of the present invention is performed by carrying out, for example, Step S12. Furthermore, the step of blowing the fuse is performed by carrying out, for example, Step S14.

The features and the advantages of the present invention as described above may be summarized as follows.

According to one aspect of the present invention, an insulating film having a protruded portion is formed on the fuse. Accordingly, the laser beams can be concentrated on the surface of the fuse, and therefore, the fuse to be blown can be blown more securely. Also, the size of the hole formed in the insulating film can be reduced.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2002-212120, filed on Jul. 22, 2002 including specification, claims, drawings and summary, on which the Convention priority of the present application is based, are incorporated herein by reference in its entirety.

1. A semiconductor device comprising;
a substrate,
a fuse formed above said substrate, and blown by the radiation of light, and
an insulating film formed on said fuse and on said substrate, wherein
said insulating film comprises a flat portion disposed on said substrate, whose surface is above the surface of said fuse, and a protruded portion formed on said fuse continuously from said flat portion, and protruded from the surface of said flat portion.

2. The semiconductor device according to claim 1, wherein said fuse comprises
a barrier metal layer,
a metal layer formed on said barrier metal layer, and
an antireflection film layer formed on said metal layer.

3. The semiconductor device according to claim 1, wherein said insulating film is the uppermost layer in the semiconductor device, and said fuse is disposed immediately under said insulating film.

4. The semiconductor device according to claim 1, wherein the width of said protruded portion is equal to or larger than the width of said fuse in the cross section of the portion of said fuse that is irradiated by light.

5. The semiconductor device according claim 1, wherein the width of said fuse is 0.6 to 1.2 μm in the cross section of the portion of said fuse that reflects light.

6. The semiconductor device according to claim 1, wherein said protruded portion is protruded in a triangular ridge shape in the cross section of the portion of said fuse that is irradiated by light.

7. The semiconductor device according to claim 6, wherein said ridge portion of said protruded portion has an angle of inclination from 40 to 70 degrees to said flat portion.

8. The semiconductor device according to claim 6, wherein said fuse comprises
a barrier metal layer,
a metal layer formed on said barrier metal layer, and
an antireflection film layer formed on said metal layer.

9. The semiconductor device according to claim 6, wherein said insulating film is the uppermost layer in the semiconductor device, and said fuse is disposed immediately under said insulating film.

10. The semiconductor device according to claim 6, wherein the width of said protruded portion is equal to or larger than the width of said fuse in the cross section of the portion of said fuse that is irradiated by light.

11. The semiconductor device according claim 6, wherein the width of said fuse is 0.6 to 1.2 μm in the cross section of the portion of said fuse that reflects light.

12. A method for manufacturing a semiconductor device comprising the steps of:
forming a fuse that can be blown by the radiation of light on a substrate, and
forming an insulating film having a flat portion at a position higher than the surface of said fuse on the fuse, and a protruded portion protruding from said flat portion on said fuse, wherein
said step of forming the insulating film is performed using the high-density plasma CVD method.

13. A method for manufacturing a semiconductor device comprising the steps of:
forming a fuse that can be blown by the radiation of light on a substrate,
forming an insulating film having a flat portion at a position higher than the surface of said fuse on the fuse, and a protruded portion protruding from said flat portion on said fuse, and
blowing said fuse, wherein
said fuse blowing step is performed by radiating light on said protruded portion.
